(19) United States
(12) Patent Application Publication
(10) Pub. No.: US 2025/0102215 A1
(43) Pub. Date: Mar. 27, 2025

(54) REFRIGERATION DEVICE AND METHOD

(71) Applicant: L'Air Liquide, Societe Anonyme pour l'Etude et l’Exploitation des Procedes Georges Claude, Paris (FR)

(72) Inventors: Florian MARTIN, Paris (FR); Mathieu SZMIGIEL, Paris (FR); James BUTTERWORTH, Paris (FR)

(21) Appl. No.: 18/891,712

(22) Filed: Sep. 20, 2024

(30) Foreign Application Priority Data
Sep. 22, 2023 (FR) FR 2310050

(51) Int. Cl. F25D 3/10

(52) U.S. Cl. CPC F25D 3/102

(57) ABSTRACT

The invention relates to a cryogenic refrigeration device comprising an enclosure delimiting a fluidtight vacuum volume closed by a cover, the device comprising at least one cryogenic cooler mounted through the cover and of the type that employs a cold source of cryogenic-cycle fluid such as helium, the device comprising at least one heat-conducting plate intended to receive and cool a component and cooled by a stream of cycle fluid via a cycle-fluid circuit supplying a set of heat exchangers, the cycle-fluid circuit having a pipe conveying cycle fluid first of all to a manifold mounted on the plate, the cycle-fluid circuit having at least one transfer pipe configured to transfer cycle fluid from the manifold to at least one heat exchanger mounted on the same plate, the cycle-fluid circuit having at least one return pipe configured to return fluid that has circulated through the at least one heat exchanger to the manifold.

### CROSS REFERENCE TO RELATED APPLICATIONS

This application claims the benefit of priority under 35 U.S.C. § 119 (a) and (b) to French patent application No. FR2310050, filed Sep. 22, 2023, which is herein incorporated by reference in its entirety.

### FIELD OF THE INVENTION

The invention relates to a refrigeration device and method.

The invention relates more particularly to a cryogenic refrigeration device comprising an enclosure delimiting a fluidtight vacuum volume closed by a cover, the device comprising at least one cryogenic cooler mounted through the cover and having a first portion situated outside the enclosure and a second portion situated in the enclosure, the cryogenic cooler being of the type that employs a cold source of cryogenic-cycle fluid such as helium, the device comprising at least one heat-conducting plate intended to receive and cool a component, for example a set of cables, the at least one plate being cooled by a stream of cycle fluid via a cycle-fluid circuit supplying a set of heat exchangers respectively in a heat-exchange relationship with the plate.

The invention relates to a refrigeration device for cooling elements to a cryogenic temperature below 100 K, and notably below 50 K and/or below 4 K.

Specifically, the invention relates to refrigeration devices used to cool to very low temperatures, in the order of millikelvins (“sub-kelvin refrigeration”). These very low temperatures are conventionally obtained using a dilution refrigerator or a cryogenic cooler of the He4 or He3 Joule-Thomson type.

### BACKGROUND OF THE INVENTION

In such devices it is necessary to supply a cooling power to a temperature of, for example, 4 K to one or more refrigeration stages. An installation of this type needs to be able to be cooled quickly when brought into operation. In addition, the experimental surface area available for the samples or cables that are to be cooled needs to be optimized.

Dilution refrigerators require a supply of cooling power to a temperature of below 4 K in order to operate. This cooling power is generally supplied by gas-filled pulse tubes (in the case of “dry” dilution refrigerators), or by a bath of liquid helium (in the case of “wet” dilution refrigerators). Cooling of ³He or of a ³He—⁴He mixture is generally necessary for use at temperatures below 1 K.

However, pulse tubes have limited individual power, and a significant number, several tens, of pulse tubes are needed in order to obtain powers that are sufficient to meet current and future requirements. This number of gas-filled pulse tubes limits the experimental surface area available for cooling equipment and samples. It is also necessary to cool ³He or a ³He-⁴He mixture for use at temperatures below 2 K. In addition, the time taken to reach a cold state with this type of technology is relatively long. Thus, this solution is, however, unable to supply a very significant amount of cooling power to the samples that are to be cooled and, furthermore, generates vibrations.

In addition, the increase in the power to be extracted may be slowed by the contact thermal resistances of the plates. For high-powered dilution refrigerators, one of the critical requirements is that of pre-cooling several thousand cables or samples. This cold power may be installed in the central part of the plate in order to cool the samples or the cables at the edge of the plate. Increasing the distance between a discrete cold point that supplies the cooling power (gas-filled pulse tube) and the sample that is to be cooled runs into problems of significant thermal resistance (conduction in the large-sized plate and intermediate contact resistances). This is one reason for the drop in thermal efficiency. Thus, increasing the power does not necessarily allow for efficient cooling.

### SUMMARY OF THE INVENTION

An aim of the present invention is to overcome all or some of the aforementioned drawbacks of the prior art.

To that end, the device according to certain embodiments of the invention, in addition to being in accordance with the generic definition thereof given in the above preamble, can include that the cycle-fluid circuit has a pipe conveying cycle fluid first of all to a manifold mounted on the plate, the cycle-fluid circuit having at least one transfer pipe configured to transfer cycle fluid from the manifold to at least one heat exchanger mounted on the same plate, the cycle-fluid circuit having at least one return pipe configured to return fluid that has circulated through the at least one heat exchanger to the manifold.

Furthermore, embodiments of the invention may include one or more of the following features:
the device comprises a plurality of heat exchangers mounted on the same plate and respective transfer pipes for transferring cycle fluid from the manifold to the heat exchangers, the heat exchangers of the same plate being supplied in parallel with cycle fluid from the conveying pipe via the manifold,
the fluid-conveying pipe passes through the cover at a support plate that seals closed a passage through the cover, the support plate, the manifold and the conveying pipe being mechanically connected to one another to form a physical entity that can be fitted/removed relative to the enclosure, for example relative to the cover,
the cycle-fluid circuit has a return pipe connecting the manifold to a part of the refrigerator and configured to return the warmed cycle fluid that has circulated through all or part of the set of heat exchangers,
the return pipe passes through the cover at the support plate and is also connected to the latter and to the manifold,
the manifold is a heat exchanger in a heat exchange relationship with the plate and has an internal circuit for the circulation of the cycle fluid so as to transfer cooling power to the plate,
the heat exchanger or exchangers comprise or consist of at least one of the following: an exchanger plate mounted on or in a housing of the plate, the exchanger plate having an internal circuit for the circulation of the cycle fluid so as to transfer cooling power to the plate; a cycle-fluid circulation pipe embedded and forming a serpentine in the thickness of the plate,
the heat exchanger or exchangers are connected to the manifold via a set of fluidic couplings that can be disconnected, for example at least at one end of the transfer pipe and/or of the return pipe,
the device comprises a plurality of plates arranged in a direction of distribution through the enclosure and intended to be cooled to determined respective temperatures, at least two plates each comprising a manifold and at least one heat exchanger connected to the manifold via a transfer pipe,
the manifolds of at least two distinct plates are supplied with cycle fluid by respective conveying pipes,
the manifold of a first plate is supplied with cycle fluid by a fluid-conveying pipe, the manifold and/or the heat exchanger(s) of a second plate being supplied with cycle fluid that has circulated through at least one exchanger and/or manifold of the first plate via a set of linking pipes,
at least some of the heat exchangers are equipped with at least one of the following: an exchanger-temperature sensor; a heating member configured to regulate the temperature of the heat exchanger,
the cycle-fluid circuit comprises one or more controllable valve(s), for example on at least one fluid-conveying pipe and configured to regulate the flowrate of cycle fluid, for example as a function of a setpoint and/or of a measurement from a temperature sensor,
at least some of the heat exchangers and/or manifold are housed in corresponding respective housings formed in the respective plates, a peripheral border of the heat exchangers and/or manifold being in contact with a border that is the conjugate of the respective heat exchangers, delimiting the housing,
at least part of the set of heat exchangers and/or manifold are mounted in the respective housings in the plate by being inserted into said housings through movement that is transverse and/or parallel relative to the planes of the plates.

The invention also relates to a refrigeration method using a device according to any one of the features above or below, comprising a step of storing and/or of producing a liquid cryogenic-cycle fluid at the refrigerator, a step of circulating said cryogenic fluid in the enclosure towards the at least one manifold and from the manifold towards the at least one heat exchanger in order to cool at least the plate, the method comprising a step of returning the warmed cycle fluid that has circulated through at least one heat exchanger to a portion of the refrigerator where it can be cooled in order to repeat a cycle of circulating through the enclosure.

The invention may also relate to any alternative device or method comprising any combination of the features above or below within the scope of the claims.

Other particular features and advantages will become apparent from reading the following description, provided with reference to the figures, in which:

### BRIEF DESCRIPTION OF THE DRAWINGS

The invention will be understood better from reading the following description and from studying the accompanying figures. These figures are given only by way of illustration and do not in any way limit the invention.

FIG. 1 is a schematic and partial view, in vertical section, illustrating a first example of embodiment of a refrigeration plant according to the invention,

FIG. 2 is a schematic and partial view, in vertical section, illustrating a second example of embodiment of a refrigeration plant according to the invention,

FIG. 3 is a schematic and partial view, in vertical section, illustrating a third example of embodiment of a refrigeration plant according to the invention,

FIG. 4 is a schematic and partial view, in vertical section, illustrating a fourth example of embodiment of a refrigeration plant according to the invention,

FIG. 5 is a schematic and partial view, in vertical section, illustrating a fifth example of embodiment of a refrigeration plant according to the invention,

FIG. 6 is a schematic and partial view, in perspective, illustrating a first possible embodiment of the first example of embodiment,

FIG. 7 is a schematic view, from beneath and showing some of the hidden detail, of the detail of FIG. 6,

FIG. 8 is a schematic and partial view, in perspective, illustrating a second possible embodiment of the first example of embodiment,

FIG. 9 is a schematic view, from beneath and showing some of the hidden detail, of the detail of FIG. 8,

FIG. 10 is a schematic and partial view, in vertical section, illustrating a detail of a sixth example of embodiment of a refrigeration plant according to the invention,

FIG. 11 is a schematic and partial view, in vertical section, illustrating a detail of a seventh example of embodiment of a refrigeration plant according to the invention,

FIG. 12 is a schematic and partial view, in vertical section, illustrating a detail of an example of embodiment of a pumped-bath type of heat exchanger that can be used in the refrigeration plant according to the invention,

FIG. 13 is a schematic and partial view, in horizontal section, of the heat exchanger of FIG. 12,

FIG. 14 is a schematic and partial view, in vertical section, illustrating a detail of another example of embodiment of a heat exchanger that can be used in the refrigeration plant according to the invention.

### DETAILED DESCRIPTION OF THE INVENTION

Throughout the figures, the same reference signs relate to the same elements.

In this detailed description, the following embodiments are examples. Although the description refers to one or more embodiments, this does not mean that the features apply only to a single embodiment. Individual features of different embodiments may also be combined and/or interchanged in order to provide other embodiments.

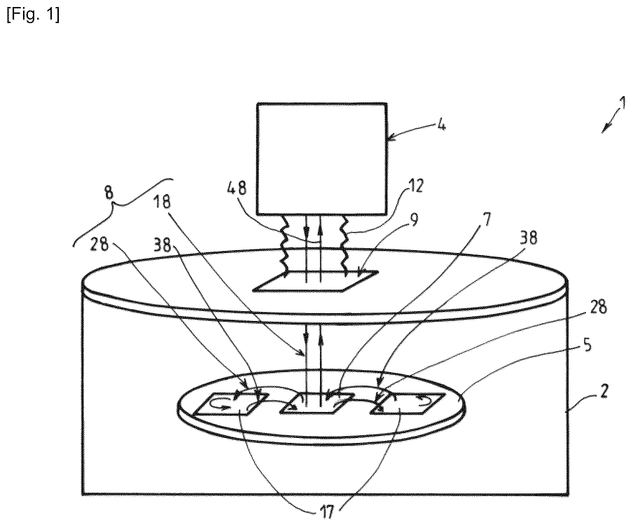

The cryogenic refrigeration plant 1 illustrated in FIG. 1 comprises an enclosure 2 delimiting a sealed volume closed by a cover 3, for example made of stainless steel or aluminium. As a preference, the volume is under vacuum and houses at least one heat-conducting plate 5 (just one in this example) forming a thermal stage. As described hereinafter, a plurality of plates may be provided in order to form thermal stages at respective temperatures that may decrease in a direction of distribution (for example vertically from the top down).

A bundle (not depicted) of cables that are to be cooled may be mounted on a set of support plate(s) mounted on the at least one plate 5. What that means to say is that cables may extend into the enclosure 2 and be in a heat-exchange relationship with the plate or plates.

Other components may be cooled at the plate or plates 5. The device may thus for this purpose comprise a set of passages formed through the cover 3 and through the plate or plates for the passage of cable(s) and/or equipment into the enclosure 2.

The at least one plate 5 is cooled to a determined temperature by a cryogenic cooler or refrigerator 4.

The cryogenic cooler 4 may be mounted through the cover 3 and with a first portion located outside the enclosure 2 and a second portion located inside the enclosure 2.

The cryogenic cooler 4 preferably comprises a cryogenic-cycle fluid (for example based on helium) and a cycle-fluid circuit 8 that circulates the cycle fluid and brings it into a heat-exchange relationship at at least one plate 5.

The set of plates is cooled by a stream of cycle fluid via the cycle-fluid circuit 8 that supplies a set of heat exchanger(s) 17 in a respective heat-exchange relationship with the plate 5.

What that means to say is that, rather than cooling the plate or plates 5, 6 by conduction solely using gas-filled pulse tubes for example or a bath of helium, the device 1 makes provision for transferring cooling power via a stream of cycle fluid.

As a preference, the cycle fluid contains or consists of helium. The cycle fluid may be cooled in a supercritical or superfluid state for example to a temperature below 4 K or below 2 K before being placed in a heat exchange relationship with the plate or plates 5, 6. This allows the cooling power to be distributed very efficiently to where it is needed.

As mentioned and illustrated, the cryogenic cooler 4 may be mounted through the cover 3 and may have a first end or portion located outside the enclosure 2 and a second end or portion located inside the enclosure 2. The cooler 4 is configured to supply cold at its second portion.

The cooler 4 is, for example, of the type using a cold source of liquefied cycle fluid such as helium or nitrogen. The cooling power of the refrigerator is stored and/or produced at its first end and this cooling power is transferred to the plates 5, 6 via a stream of the cycle fluid which transfers cooling power from the first end towards the second end of the cooler. After exchanging heat with the plate or plates 5, 6, the cycle fluid is returned to a warm part of the cooler 4 in order to repeat the cycle (compression, expansion, etc.).

The cooler 4 comprises for example a cycle circuit configured to subject the cycle fluid to a thermodynamic cycle which brings the cycle fluid at at least one cold end of the cycle circuit to a determined cryogenic temperature via expansion of the compressed cycle fluid. The cycle-fluid circuit comprising for example a mechanism for compressing the cycle fluid (compressor(s)), at least one cooling member for cooling the cycle fluid (heat exchanger(s)), an expansion mechanism for expanding the cycle fluid (valve(s) and/or turbine(s)) and at least one warming member (heat exchanger(s)) for warming the expanded cycle fluid. The warming and the cooling may be performed in part at least by one or more countercurrent-flow heat exchanger(s) for simultaneously cooling and warming two parts of the cycle circuit.

The cryogenic cooler 4 uses, for example, a cycle fluid comprising at least one of the following: helium, hydrogen, nitrogen, argon, neon. The device 1 comprises a circuit 8 with a set of conveying pipe(s) 18 conveying at least some of the cold cycle fluid towards the plate or plates 5, 6 to be cooled.

As visible in FIG. 1, the cycle-fluid circuit 8 has a conveying pipe 18 conveying cycle fluid first of all to a manifold 7 mounted on the plate 5. The cycle-fluid circuit 8 also has a transfer pipe 28 configured to transfer cycle fluid from the manifold 7 to at least one heat exchanger 17 mounted on the same plate 5 (two heat exchangers 17 in this example).

The cycle-fluid circuit 8 has at least one return pipe 38 configured to return fluid that has circulated through the at least one heat exchanger 17 to the manifold 7.

This architecture allows the cold cycle fluid to be transferred to a manifold supported by the plate 5 and this cooling power to be distributed to one or more heat exchangers 7 of the plate 5.

This allows cooling power to be distributed efficiently and uniformly over large surface areas using a reduced number of conveying pipes 18 (notably just one pipe).

In instances (like that illustrated in FIG. 1) in which a plurality of heat exchangers 17 are mounted on the same plate 5, respective transfer pipes 28 may be provided for transferring cycle fluid from the manifold 7 to the heat exchangers 17. In such instances, the heat exchangers 17 of the same plate 5 may be supplied in parallel with cycle fluid from the conveying pipe 18 via the manifold 7.

After having circulated through the heat exchangers 17, the relatively hotter cycle fluid may be returned to the manifold 7 via respective return pipes 38. This hot cycle fluid may then be returned to the refrigerator 4 via a return pipe 48 so that it can, for example, be cooled again and perform a repeat cycle.

It should be noted that the conveying pipe 18 (or conveying pipes 18, as there may be a plurality of these) and the return pipe 48 (or the return pipes 48, as there may be a plurality of these) are preferably contained in a vacuum insulated heat shield or sleeve 12 in order to avoid heat ingress. The sleeve 12 may in particular be provided between the cover 3 and the exterior portion of the refrigerator 4.

The fluid-conveying pipe 18 (and the return pipe 48) may pass through the cover 3 at a support plate 9 or flange sealing closed a passage through the cover 3.

The support plate 9, the manifold 7 and the conveying pipes 18 and return pipes 48 may be mechanically connected to one another to form a physical entity that can be fitted/removed relative 2 to the enclosure 2, for example vertically relative to the cover 3. For example, a tool such as a vertical post or guide may be used to support this assembly during operations of fitting/removal relative to the enclosure and to the plates.

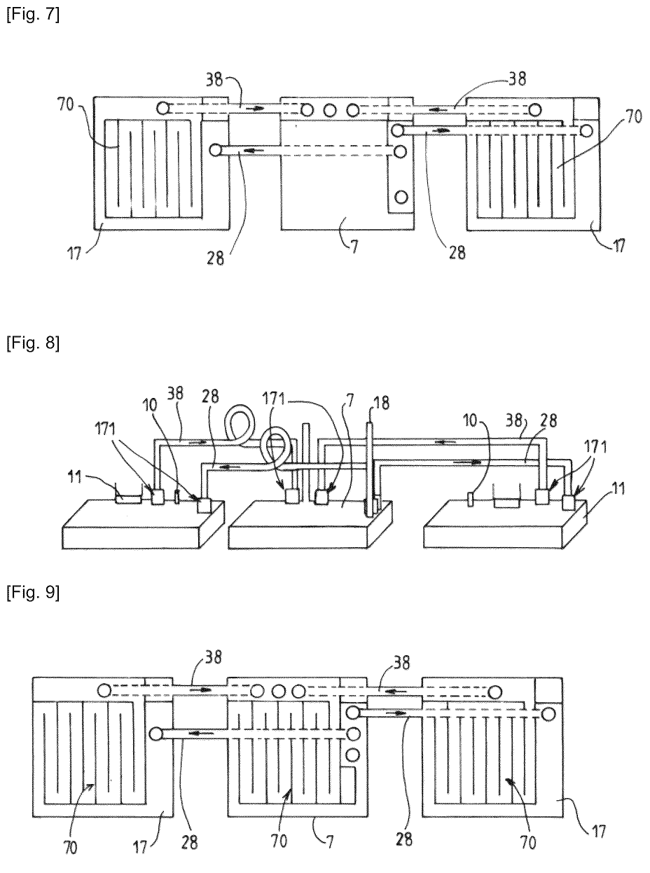

FIG. 6 and FIG. 7 illustrate an example of a structure of manifold 7 associated with two heat exchangers 17 and which receives the cold cycle fluid (via the conveying pipe 18) and immediately distributes it to the heat exchangers 17 via transfer pipes 28. In addition, the manifold 7 receives the streams of cycle fluid that has circulated through the heat exchangers 17 via return pipes 38 and may return this relatively hotter cycle fluid, for example in the return pipe 48. What that means to say is that, in this example, unlike the heat exchangers 17, the manifold 7 is not configured to perform an optimized exchange of heat with the plate that supports it. For example, the heat exchangers 17 comprise an internal cycle-fluid circulation circuit 70 that forms a serpentine coil to optimize the exchange of heat with the plate 5. The manifold 7 may, as illustrated, be devoid of such an internal circuit.

By contrast, and as illustrated in the variant of FIG. 8 and FIG. 9, the manifold 7 may also be a heat exchanger in a heat exchange relationship with the plate 5 (configured for that), for example by having an internal circuit 70 for the circulation of the cycle fluid so as to transfer cooling power to the plate 5.

As illustrated, the heat exchangers 17 may be connected to the manifold 7 via a set of fluidic couplings 171 which can be disconnected. For example, at least one of the ends of the transfer pipe 28 and/or of the return pipe 38 may be equipped with such a coupling 171 allowing easy fitting/removal with respect to the manifold/exchanger. This in particular allows the exchangers 17 to be coupled easily to the manifold 7 after the fitting, or before the removal, of the set of manifold(s) 7 and pipes 18, 48, as described hereinabove.

Alternatively, or in combination, some of the set of pipes of the cycle-fluid circuit 8 that allow the cycle fluid to be circulated to or from the heat exchangers 7, 17 and/or manifolds 7 may be soldered and/or brazed to the heat exchangers 7, 17 or manifolds 7.

At least some of these pipes of the cycle-fluid circuit 8 that allow the cycle fluid to be circulated to or from the heat exchangers 7, 17 and/or from or to the manifold(s) 7 may be configured to exhibit a determined flexibility, for example a bent portion, able to absorb the dimensional variations caused by the variations in temperature between the ambient temperature when shut down and a cryogenic operating temperature of the device 1.

In the aforementioned examples, the heat exchangers 17 comprise or consist of an exchanger plate mounted on or in a housing in the plate 5 and which has an internal circuit 70 for the circulation of the cycle fluid so as to transfer cooling power to the plate 5.

FIG. 6 and FIG. 8 furthermore schematically illustrate the fact that at least some of the heat exchangers 17 may be fitted with a sensor 10 for measuring the temperature of the exchanger and/or with a heating member 11 configured to regulate the temperature of the heat exchanger 17. For example, each heat exchanger 17 has such a sensor 10 and/or such a warming member 11.

Likewise, the warming member or members 11 may make it possible to provide this temperature control.

Thus, the device 1 may comprise one or more controllable valve(s) 13 in the cycle-fluid circuit 8, for example on at least one fluid-conveying pipe 38 and configured to regulate the flowrate of cycle fluid, for example as a function of a setpoint and of a measurement from the temperature sensor(s) 10 (see FIG. 11).

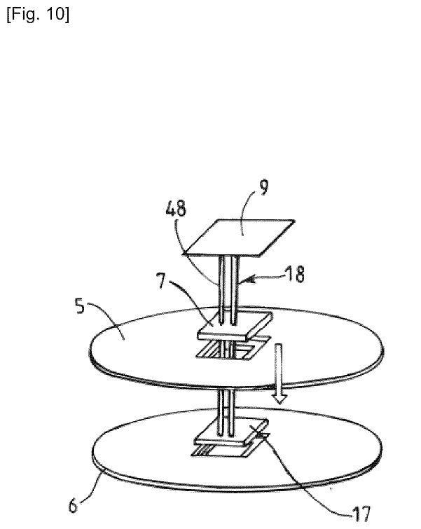

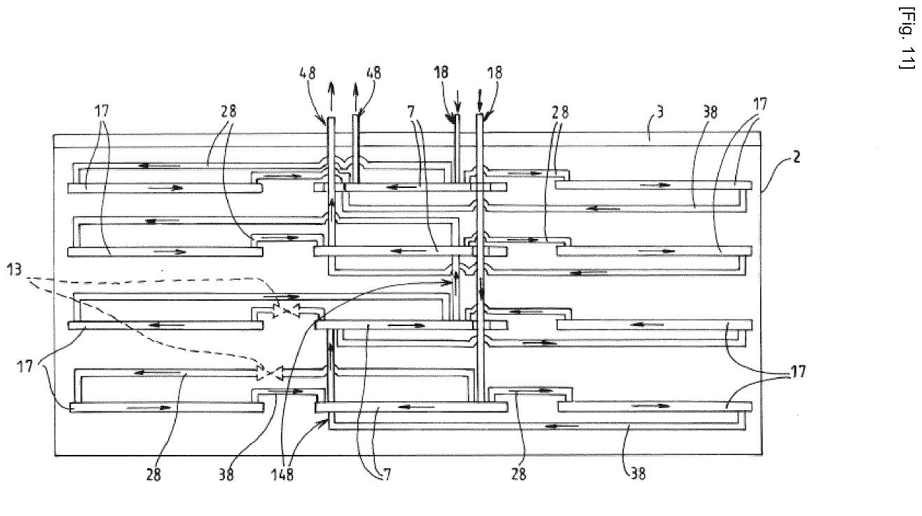

At least some of the heat exchangers 17 and/or manifold 7 may be housed in corresponding respective housings formed in the respective plates 5, 6. For example, a peripheral border of the heat exchangers 17 and/or manifold 7 is in contact with a border that is the conjugate of the respective heat exchangers 17, delimiting the housing (see FIG. 10).

At least part of the set of heat exchangers 17 and/or manifold 7 may be mounted in the respective housings in the plates by being inserted into said housings through movement that is transverse relative to the planes of the plates 5, 6 (see vertical fitting FIG. 10).

Naturally, these housings may open onto the edge of the plate so as to allow the heat exchangers 17 and/or manifolds 7 to be fitted/removed in a direction parallel to the plane of the plate.

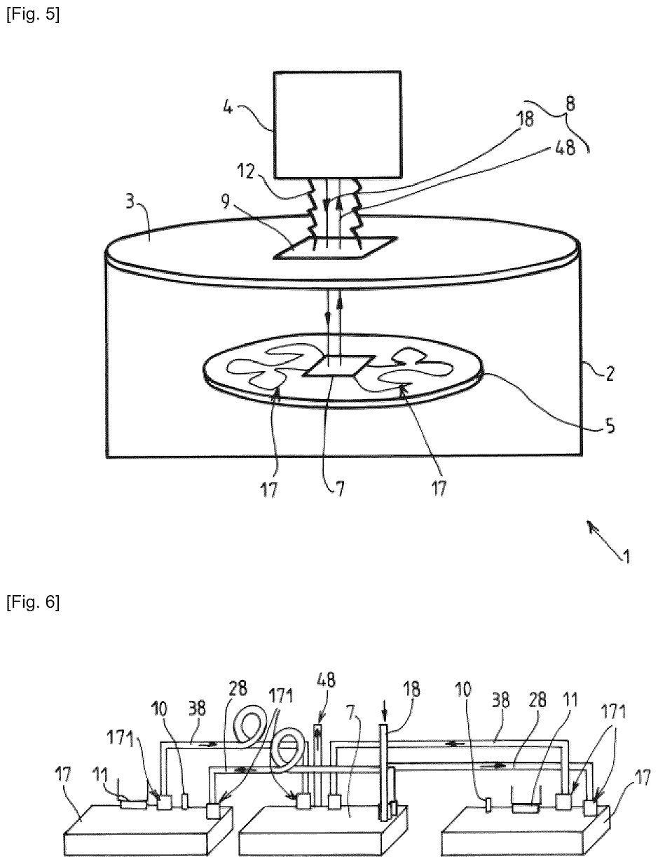

However, this form of embodiment is nonlimiting. Thus, for example, at least one of the heat exchangers 17 may be a simple cycle-fluid circulation pipe embedded and forming a serpentine in the thickness of the plate 5 (see FIG. 5). In such a case, the temperature sensor 11, if present, may measure the temperature at the plate for example.

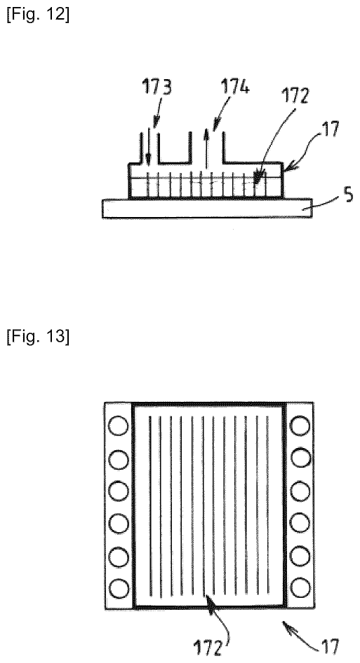

Likewise, as a variant or in combination, at least one heat exchanger 7 may comprise a pumped bath system as illustrated in FIG. 12 and FIG. 13. What that means to say is that the heat exchanger 17 comprises an internal volume fitted with fins 172 and intended to receive a volume of cycle fluid via at least an inlet 173 and an outlet 174 which is provided so as to allow this fluid to circulate. The heat exchanger 171 is for example laid on a plate 5 or on a support plate itself placed on the plate 5.

It should also be noted that at least one of the heat exchangers 17 may be a collection of a plurality of exchangers in series on the plate. What that means to say is that one transfer pipe 28 may supply a first heat exchanger 17 which then itself supplies at least one other heat exchanger 17 in series.

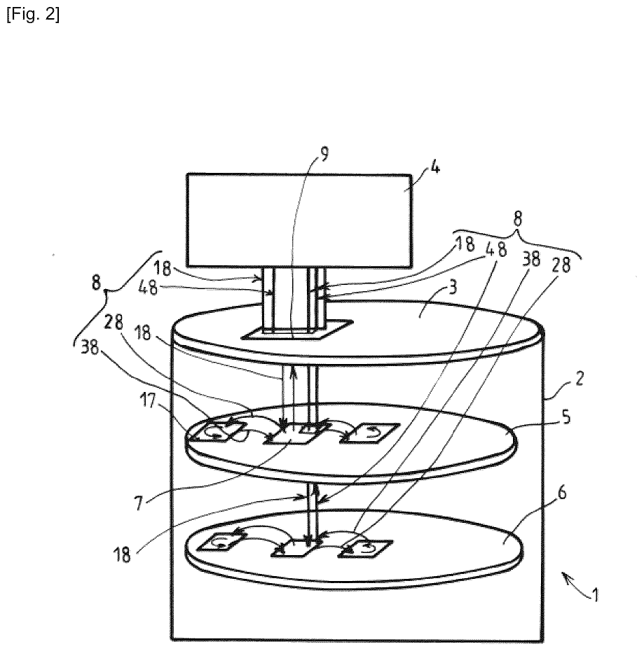

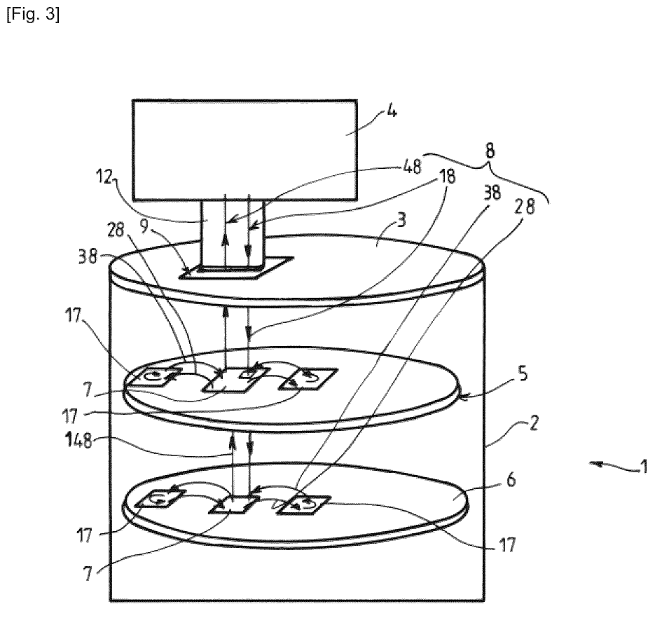

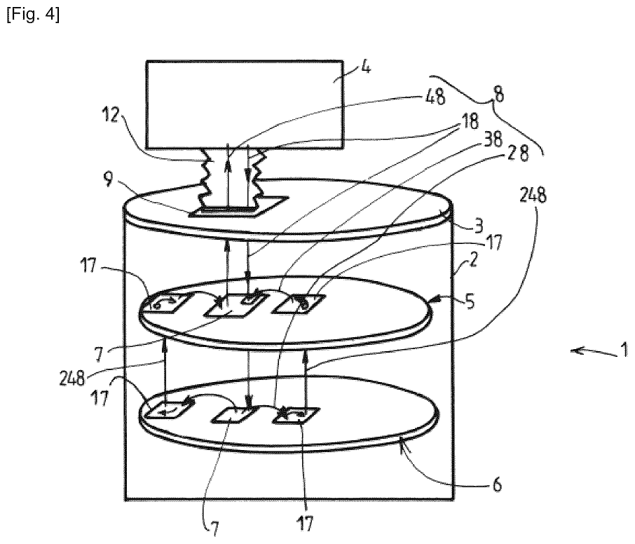

As illustrated in FIG. 2, FIG. 3 and FIG. 4, the device 1 may comprise a plurality of plates 5, 6 (two in this example) arranged in a direction of distribution in the enclosure 2, for example a vertical direction. The plates 5, 6 are intended to be cooled to determined respective temperatures, for example that decrease toward the bottom of the enclosure 2.

Each of the plates 5, 6 has a manifold 7 and two heat exchangers 17, 17 connected to the manifold 7 via transfer pipes 28 and return pipes 38 as described above.

In the embodiment of FIG. 2, the manifolds 7 of the two plates 5, 6 are connected to the cryogenic cooler by respective conveying pipes 18 and respective pipes 48 which are distinct. What that means to say is that the two manifolds 7 and respective plates are applied with distinct streams of cycle fluid at respective temperatures that may differ. These two streams may be two distinct streams from the one same refrigerator circuit and/or streams belonging to two distinct coolers. As illustrated, the conveying pipe 18 and return pipe 48 of the lowermost plate 6 may pass through or via the manifold 7 of the previous (upper) plate. Likewise, the manifolds 7 of the two (or more where applicable) plates may be joined together so that they can be fitted or removed from the enclosure 2 together, for example vertically.

In the embodiment of FIG. 3, the first manifold 7 of a first, lower, plate 6 is connected to the cryogenic cooler by a conveying pipe 18 (through the manifold 7 of the second, upper, plate). The first manifold 7 supplies the heat exchangers 17 of the first plate via respective transfer pipes 28 and recovers the cycle fluid that has circulated through the heat exchangers 17 of this first plate 6 and then directs this fluid towards the second manifold 7 of the second, upper, plate 5. This second manifold 7 supplies the heat exchangers 17 of the second plate 5 (transfer pipes) and recovers the cycle fluid (return pipes 38) before returning it to the cooler (return pipe 48).

The embodiment of FIG. 4 differs from that of FIG. 3 only in that the cycle fluid that has circulated through the heat exchangers 17 of the first plate 6 is then sent directly respectively into the heat exchangers 17 of the first plate (via the linking pipes 248 without passing via the manifold 7 of the second plate 5).

What that means to say is that, in these two embodiments, the manifold 7 or the heat exchangers 17 of a second plate 5 are supplied with relatively hotter cycle fluid that has already circulated through at least one heat exchanger 17 and/or manifold of a (relatively colder) first plate 6. The same stream of cycle fluid is therefore used for cooling two plates 5, 6 in series.

This then allows the cycle fluid to be conveyed first of all to a first set of heat exchangers 17 which is intended to be cooled to a first temperature and then allows the cycle fluid that has circulated through the first set of heat exchangers 17 to be transferred to a second set of heat exchangers 7 which is intended to be cooled to a second temperature higher than the first temperature.

Thus, two distinct manifolds 7 and plates 5, 6 can be cooled to respective temperatures that may be different using the one same stream of cycle fluid.

This may naturally be extended to a greater number of plates than two.

The cycle fluid circulating in the conveying pipe 18 and/or in the return pipe 48 is in liquid, gaseous or supercritical form, and the state of the fluid in the conveying pipe 18 may differ from the state in the return pipe 48.

Just like the manifolds 7 of several plates, the heat exchangers 17 of the one same plate or of distinct plates may where applicable be connected mechanically to one another by a set of pipes of the cycle-fluid circuit 8 that circulate the cycle fluid to or from the heat exchangers. This means that the entirety can be fitted into the enclosure 2 in a single operation.

Heat exchangers 17 and/or manifolds 7 may be connected mechanically to one another solely by the set of pipes of the cycle-fluid circuit 8.

The invention is not restricted to the described or illustrated examples comprising one or two plates.

The illustrated shape (circular) of the plates is nonlimiting (any other shape, for example polygonal, may be envisaged).

The device 1 may comprise more than two plates distributed in a direction of distribution in the enclosure 2 and forming thermal stages. These plates may be cooled to respective determined temperatures, for example that decrease in the direction of distribution.

FIG. 11 schematically illustrates a variant with four manifolds. The first manifold 7 at the bottom end receives a stream of cycle fluid from the conveying pipe 18 and distributes it in parallel to two heat exchangers 17 via transfer pipes 28. These two exchangers then return the fluid to it via return pipes 38. The first manifold 7 then sends this stream of cycle fluid to a second manifold 7 above it, via a linking pipe 148. The second manifold 7 distributes it in parallel to two heat exchangers 17 via transfer pipes 28. These two exchangers 17 then return the fluid to it via return pipes 38. The second manifold 7 then sends this stream of cycle fluid to a third manifold 7 above it, via a linking pipe 148. This third manifold 7 then distributes the fluid in parallel to two heat exchangers 17 via transfer pipes 28 These two exchangers 17 then return the fluid to it via return pipes 38. This third manifold returns the cycle fluid to the cooler via a return pipe 48. The fourth manifold, on the other hand, receives a stream of cycle fluid from another conveying pipe 18 and distributes it in parallel to two heat exchangers 17 which are connected to it via transfer pipes 28. These two heat exchangers 17 then return the fluid to it via return pipes 38. This fourth manifold 7 then returns the cycle fluid to the cooler via another return pipe 48.

The plates may be spaced away from one another via supports or spacers, for example made of a composite material.

At least one of the plates may be connected to a heat shield (a collection of wall(s)) forming a volume enveloping at least one next plate. The plate and the corresponding shield envelop the next plates and shields in a direction of distribution. What this means to say is that the plates and shields may fit one inside the next in the manner of “nesting” components.

In an operating configuration, the cover 3 may be at ambient temperature (at least in the case of the exterior face thereof), and the plates inside the enclosure 2 may be cooled to decreasing temperatures (for example to 90 K, 50 K, 10 K and 3 K respectively in cases where there are four plates).

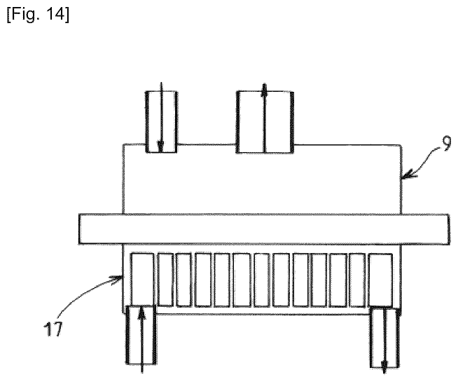

As illustrated schematically in FIG. 14, at least one of the heat exchangers 17 described above may be used to exchange heat with another fluid of the plant, for example so as to cool this other fluid. For example, the heat exchanger is placed in the heat-exchange relationship with, for example, another heat exchanger 19 receiving a hotter stream of fluid, for example of He3 or a mixture of He3-He4, that is to be cooled. As illustrated, the two exchangers may be back-to-back and/or positioned one on each side of an exchanger plate and/or of a plate.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

We claim:

1. A cryogenic refrigeration device comprising:
an enclosure delimiting a fluidtight vacuum volume closed by a cover,
a cryogenic cooler mounted through the cover and having a first portion situated outside the enclosure and a second portion situated in the enclosure, the cryogenic cooler being configured to employ a cold source of cryogenic-cycle fluid,
a heat-conducting plate configured to receive and cool a component, the at least one plate being cooled by a stream of cycle fluid via a cycle-fluid circuit supplying a set of heat exchangers of the cryogenic refrigeration device which are respectively in a heat-exchange relationship with the plate,
wherein the cycle-fluid circuit has a pipe conveying cycle fluid to a manifold of the cryogenic refrigeration device which is mounted on the plate, the cycle-fluid circuit having at least one transfer pipe configured to transfer cycle fluid from the manifold to at least one heat exchanger mounted on the same plate, the cycle-fluid circuit having at least one return pipe configured to return fluid that has circulated through the at least one heat exchanger to the manifold.

2. The refrigeration device according to claim 1, further comprising: a plurality of heat exchangers mounted on the same plate and respective transfer pipes for transferring cycle fluid from the manifold to the heat exchangers, the heat exchangers of the same plate being supplied in parallel with cycle fluid from the conveying pipe via the manifold.

3. The refrigeration device according to claim 1, wherein the fluid-conveying pipe passes through the cover at a support plate that seals closed a passage through the cover, the support plate, the manifold and the conveying pipe being mechanically connected to one another to form a physical entity that can be fitted/removed relative to the enclosure, for example relative to the cover.

4. The refrigeration device according to claim 1, wherein the cycle-fluid circuit has a return pipe connecting the manifold to a part of the refrigerator and configured to return the warmed cycle fluid that has circulated through all or part of the set of heat exchangers.

5. The refrigeration device according to claim 4, wherein the return pipe passes through the cover at the support plate and is also connected to the latter and to the manifold.

6. The refrigeration device according to claim 1, wherein the manifold is a heat exchanger in a heat exchange relationship with the plate and has an internal circuit for the circulation of the cycle fluid so as to transfer cooling power to the plate.

7. The refrigeration device according to claim 1, wherein the heat exchanger or exchangers comprise or consist of at least one of the following: an exchanger plate mounted on or in a housing of the plate, the exchanger plate having an internal circuit for the circulation of the cycle fluid so as to transfer cooling power to the plate; a cycle-fluid circulation pipe embedded and forming a serpentine in the thickness of the plate.

8. The refrigeration device according to claim 1, wherein the heat exchanger or exchangers are connected to the manifold via a set of fluidic couplings that can be disconnected, for example at least at one end of the transfer pipe and/or of the return pipe.

9. The refrigeration device according to claim 1, further comprising a plurality of plates arranged in a direction of distribution through the enclosure and intended to be cooled to determined respective temperatures, at least two plates each comprising a manifold and at least one heat exchanger connected to the manifold via a transfer pipe.

10. The refrigeration device according to claim 9, wherein the manifolds of at least two distinct plates are supplied with cycle fluid by respective conveying pipes.

11. The refrigeration device according to claim 10, wherein the manifold of a first plate is supplied with cycle fluid by a fluid-conveying pipe, the manifold and/or the heat exchanger(s) of a second plate being supplied with cycle fluid that has circulated through at least one exchanger and/or manifold of the first plate via a set of linking pipes.

12. The refrigeration device according to claim 1, wherein at least some of the heat exchangers are equipped with at least one of the following: an exchanger-temperature sensor; a heating member configured to regulate the temperature of the heat exchanger.

13. The refrigeration device according to claim 1, wherein the cycle-fluid circuit comprises one or more controllable valve(s), for example on at least one fluid-conveying pipe and configured to regulate the flowrate of cycle fluid, for example as a function of a setpoint and/or of a measurement from a temperature sensor.

14. The refrigeration device according to claim 1, wherein at least some of the heat exchangers and/or manifold are housed in corresponding respective housings formed in the respective plates, a peripheral border of the heat exchangers and/or manifold being in contact with a border that is the conjugate of the respective heat exchangers, delimiting the housing.

15. The refrigeration device according to claim 14, wherein at least part of the set of heat exchangers and/or manifold are mounted in the respective housings in the plates by being inserted into said housings through movement that is transverse and/or parallel relative to the planes of the plates.

16. A refrigeration method comprising the steps of:
providing the refrigeration device according to claim 1;
storing and/or of producing a liquid cryogenic-cycle fluid at the refrigerator,
circulating said cryogenic fluid in the enclosure towards the at least one manifold and from the manifold towards the at least one heat exchanger in order to cool at least one plate,
returning the warmed cycle fluid that has circulated through at least one heat exchanger to a portion of the refrigerator where the warmed cycle fluid is cooled in order to repeat a cycle of circulating through the enclosure.
